(19) United States
(12) Patent Application Publication
(10) Pub. No.: US 2010/0315037 A1
(43) Pub. Date: Dec. 16, 2010

(54) RESISTOR TESTING CIRCUIT AND BATTERY CHARGER INCLUDING RESISTOR TESTING CIRCUIT

(75) Inventors: Masami AIURA, Sendai (JP); Manabu Ishida, Sendai (JP); Noriaki Tanaka, Sendai (JP)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC., Austin, TX (US)

(21) Appl. No.: 12/784,496

(22) Filed: May 21, 2010

(30) Foreign Application Priority Data
Jun. 3, 2009 (JP) 2009-133953

(51) Int. Cl. H02J 7/00; G01R 31/02

(52) U.S. Cl. 320/107

(57) ABSTRACT

A resistor testing circuit for a battery charger that tests divisional resistors used to estimate the resistance of a thermistor in a battery pack. The battery charger when activated conducts a self test. In the self test, switches are sequentially switched to form groups of resistors and test the connection state of the resistors groups. When a defect is detected by the self test, the battery charger stops performing charging. When no defects are detected by the self test, the thermistor of the battery pack is used to estimate temperature. The charging current is determined in correspondence with the temperature. Then, charging is started.

### BACKGROUND OF THE INVENTION

The present invention relates to a testing circuit for a battery charger and more particularly, to a battery charger with a resistor testing circuit.

Rechargeable batteries, such as lithium ion batteries, are often used in electronic devices. To safely charge, for example, a lithium ion battery, the temperature of the battery must be monitored to control the charging current. Japanese Laid-Open Patent Publication No. 2003-199262 (page 1, FIG. 1) discusses a technique for charging, discharging, and recharging a battery in an environment in which thermal conditions easily change. In this technique, a battery charger, which charges a battery, includes a charging circuit having a charging current output coupled to the battery, and a temperature sensor, which detects the battery temperature. When the battery is coupled to the temperature sensor and the charging circuit, the charging current is set in accordance with the temperature.

A structure for estimating the temperature will now be discussed with reference to FIGS. 10A to 10C. As shown in FIG. 10A, a battery pack 10 includes a battery cell CL1 and a thermistor TH1. The thermistor TH1 has a negative temperature coefficient (NTC) and measures temperature based on a resistivity that varies in accordance with the temperature. A battery charger 20 executes charge control using a plurality of temperature threshold values, as shown in FIGS. 10B and 10C. For example, current and voltage are restricted differently in a low temperature range of temperatures T1 to T2, a normal temperature range of temperatures T2 to T5, and a high temperature range of temperatures T5 to T6. The temperature range of temperatures T3 to T4 is most optimal for charging.

The battery charger includes a group of resistors corresponding to the temperature threshold values to estimate the resistance of the thermistor TH1, which is used to execute control in accordance with the temperature. Such a resistor group may be of a series type or a parallel type. As shown in FIG. 11A, in a series type resistor group, resistors R1 to R4 are connected in series, and a group of switches (switches SW1 to SW4) are arranged to supply voltage to connection nodes of the resistors. As shown in FIG. 11B, in a parallel type resistor group, resistors R91 to R94 are connected in parallel, and switches SW1 to SW4 are arranged to supply voltage to each of the resistors.

In the battery charger, a comparator CP1 compares the voltage between the two terminals of the thermistor TH1 with a reference voltage to estimate the temperature threshold value of the battery pack. The voltage between the two terminals of the thermistor TH1 is determined from the resistance obtained by combining the resistors R1 to R4 or the resistance obtained by combining the resistors R91 to R94. Referring to FIG. 11C, when estimating the temperature threshold value, the switches SW1 to SW4 are sequentially switched to detect the temperature threshold value by connecting different resistors to the thermistor TH1.

When a wire breakage or the like occurs in the thermistor, accurate measurement is hindered. Accordingly, Japanese Laid-Open Patent Publication No. 10-334360 (page 1, FIG. 1) discusses a digital heat detector connected to a monitoring line for a fire alarm receiver to monitor abnormalities, such as wire breakage and short circuiting of the temperature detection circuit. This digital heat detector includes a temperature detection circuit and an A/D converter. The temperature detection circuit includes a thermistor. The A/D converter converts the voltage output of the temperature detection circuit to a temperature measurement value of a digital signal. The digital heat detector compares the temperature measurement value with a threshold value for wire breakage or the like to determine the occurrence of a wire breakage or the like and sends a determination signal to the monitoring line.

Japanese Laid-Open Patent Publication No. 9-115074 (page 1, FIG. 1) discusses a fire alarm that performs wire breakage detection of a thermistor, which is a heat sensing element, when conducting a test to check normal functioning. In this fire alarm, when a fire outbreaks, the ambient temperature rises and decreases the resistance of the thermistor. When the temperature becomes greater than or equal to an activation temperature, a comparator of a fire determination circuit outputs a warning signal. This issues a warning with a buzzer drive signal. The pushing of a testing switch also outputs a warning signal from the comparator by connecting in parallel a fire substitution resistor with a sensitivity adjustment resistor.

In the circuits of FIGS. 11A and 11B, the connection of the resistors R1 to R4 or the R91 to R94 to a terminal must be ensured for correct temperature estimation. To test such a connection, an electronic circuit may undergo a joint test action group (JTAG) boundary scan, which is for testing the operation of a circuit. This allows for location of abnormalities. However, such testing is intended for digital circuits and not suitable for an analog circuit that includes a thermistor having a negative temperature coefficient. Further, the testing of a battery charger, in particular, must be performed efficiently in a reproducible manner.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a diagram showing the structure of a battery charger according to a first embodiment of the present invention;

FIG. 2 is a flowchart showing the procedures for testing the battery charger of the first embodiment;

FIGS. 3A to 3C are diagrams showing operational states for testing the battery charger of the first embodiment, in which FIG. 3A shows a first operational state, FIG. 3B shows a second operational state, and FIG. 3C shows a third operational state;

FIGS. 4A to 4C are diagrams showing operational states for testing the battery charger of the first embodiment, in which FIG. 4A shows a fourth operational state, FIG. 4B shows a fifth operational state, and FIG. 4C shows a sixth operational state;

FIGS. 5A to 5C are diagrams showing operational states for testing the battery charger of the first embodiment, in which FIG. 5A shows a seventh operational state, FIG. 5B shows an eighth operational state, and FIG. 5C shows a ninth operational state;

FIG. 6 is a flowchart showing the procedures for testing a battery charger in a modification of the first embodiment;

FIG. 7 is a diagram showing the structure of a resistor testing circuit according to a second embodiment of the present invention;

FIGS. 8A and 8B are diagrams showing operational states for testing the battery charger in the second embodiment, in which FIG. 8A shows a first operational state, and FIG. 8B shows a second operational state;

FIGS. 9A and 9B are diagrams showing operational states for testing the battery charger in the second embodiment, in which FIG. 9A shows a third operational state, and FIG. 9B shows a fourth operational state;

FIG. 10A is a diagram showing a battery pack connected to a battery charger;

FIG. 10B is a chart showing the charging current;

FIG. 10C is a chart showing the charging voltage;

FIG. 11A is a diagram showing a series-type resistor group used to estimate the resistance of a thermistor in a battery charger;

FIG. 11B is a diagram showing a parallel-type resistor group used to estimate the resistance of a thermistor in a battery charger; and

FIG. 11C is a timing chart of the voltage applied to the thermistor.

### DETAILED DESCRIPTION OF THE INVENTION

The present invention provides a resistor testing circuit, which is for testing divisional resistors in a battery charger, and a battery charger including such a resistor testing circuit.

One aspect of the present invention is a resistor testing circuit for a battery charger including a plurality of divisional resistors connected in series to a thermistor for measuring the temperature of a battery. A switch is arranged in correspondence with each of the divisional resistors to control supply of a reference voltage. A comparator compares a voltage between the two terminals of the thermistor with the reference voltage. A power supply supplies the battery with a charging current. The resistor testing circuit tests a connection state of the divisional resistors. The resistor testing circuit includes the switches and a control unit that controls the power supply. The control unit sequentially switches the switches and obtains a comparison result from the comparator. Further, the control unit conducts a test that allows the power supply to perform charging only when the comparison result is free from abnormalities.

A further aspect of the present invention is a battery charger including a plurality of divisional resistors connected in series to a thermistor for measuring the temperature of a battery. A switch is arranged in correspondence with each of the divisional resistors to control supply of a reference voltage. A comparator compares a voltage between the two terminals of the thermistor with the reference voltage. A power supply supplies the battery with a charging current. A resistor testing circuit includes a control unit that controls the switches and the power supply. The resistor testing circuit tests a connection state of the divisional resistors. The control unit sequentially switches the switches and obtains a comparison result from the comparator. Further, the control unit conducts a test that allows the power supply to perform charging only when the comparison result is free from abnormalities.

Other aspects and advantages of the present invention will become apparent from the following description, taken in conjunction with the accompanying drawings, illustrating by way of example the principles of the invention.

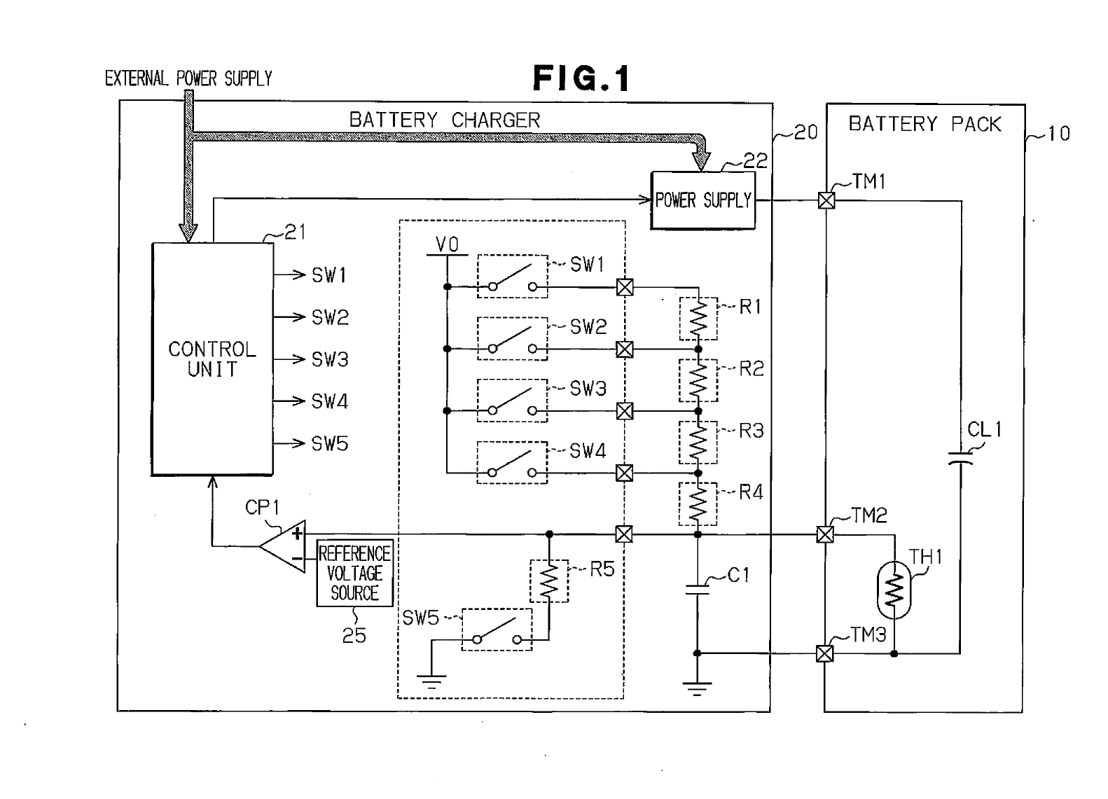

A resistor testing circuit according to a first embodiment of the present invention will now be discussed with reference to FIGS. 1 to 5. In the first embodiment, a test is conducted on resistors used to estimate the temperature when a battery pack 10 is connected to a battery charger 20 for charging.

Referring to FIG. 1, the battery pack 10 includes a battery cell CL1 and a thermistor TH1. The battery cell CL1 is connected to external terminals TM1 and TM3. Current for charging the battery cell CL1 is supplied from the external terminal TM1. The external terminal TM3 is a common terminal supplied with ground voltage. Further, a thermistor TH1 is connected to an external terminal TM2 and the external terminal TM3. The battery charger 20 supplies the external terminal TM2 with voltage for estimating the resistance of the thermistor TH1.

The battery charger 20 includes a power supply 22 for charging the battery cell CL1, resistors R1 to R4, which are used to estimate the temperature state, a comparator CP1, a reference voltage source 25, and a control unit 21.

The power supply 22 is a current source that supplies current having a current value corresponding to the temperature state of the battery pack 10.

The resistors R1 to R4 form a resistor group used to estimate the resistance of the thermistor TH1 in the battery pack 10. In the first embodiment, the resistor group is of a series type in which the resistors R1 to R4 are connected in series. The first resistor R1 has one end connected to a switch SW1. A switch SW2 is connected to a node between the other end of the resistor R1 and one end of the resistor R2. A switch SW3 is connected to a node between the other end of the resistor R2 and one end of the resistor R3. A switch SW4 is connected to a node between the other end of the resistor R3 and one end of the resistor R4. The switches SW1 to SW4 are each supplied with a reference voltage V0.

Further, the other end of the resistor R4 is connected to the external terminal TM2 of the battery pack 10. As a result, the reference voltage V0 is divided into a voltage corresponding to the resistance obtained by the combination of the resistors R1 to R4 and the resistance of the thermistor TH1. The other end of the resistor R4 is further grounded via a capacitor C1. The capacitor C1 is used to absorb sudden voltage changes caused by one reason or another, such as external noise. The other end of the resistor R4 is also grounded via a resistor R5 and a switch SW5. The resistor R5 is a pull-down resistor for discharging the capacitor C1. Further, the other end of the resistor R4 is connected to a non-inverting input terminal of the comparator CP1. Accordingly, the non-inverting input terminal of the comparator CP1 receives the voltage (divisional voltage) obtained by dividing the reference voltage V0 in correspondence with the resistance obtained by the combination of the resistors R1 to R4 and the resistance of the thermistor TH1. The reference voltage source 25 supplies an inverting input terminal of the comparator CP1 with voltage (reference voltage V2) for estimating the resistance of the thermistor TH1.

The resistance of each of the resistors R1 to R4 may be obtained by solving the simultaneous equations shown below.

V2=V0·R(T4)/[R(T4)+R4]

V2=V0·R(T3)/[R(T3)+R3+R4]

V2=V0·R(T2)/[R(T2)+R2+R3+R4]

V2=V0·R(T1)/[R(T1)+R1+R2+R3+R4]

Here, R(T) is the resistance corresponding to the temperature T (T1, T2, T3, T4) of the thermistor TH1.

The control unit 21 functions as a resistor test circuit and outputs a signal for controlling the switches SW1 to SW5 in synchronism. Further, the control unit 21 instructs the reference voltage source 25 of the voltage supplied to the comparator CP1. In the first embodiment, a reference voltage V1 is used when testing connections in a self-test, a reference voltage V2 is used for temperature estimation, and a reference voltage V3 is used for detecting connection of the battery pack 10. The reference voltage V1 is slightly higher than the ground voltage (e.g., 5% of the reference voltage V0). The reference voltage V3 is slightly lower than the reference voltage V0 (e.g., 95% of the reference voltage V0). Prior to charging, the control unit 21 executes control in accordance with the test results related to the connection state of the resistors R1 to R5. Further, the control unit 21 executes control in accordance with the temperature state of the battery pack 10 during charging. The control unit 21 thus holds a charging condition determination table for determining the charging conditions (charging current value) in correspondence with the temperature range.

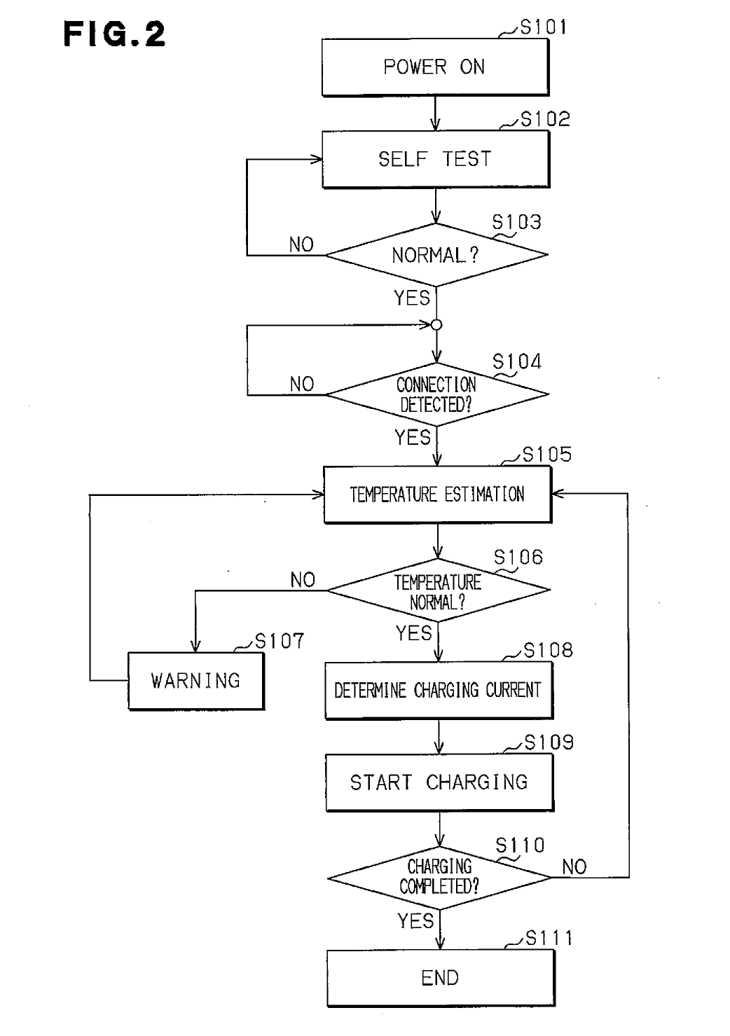

The procedures for testing the battery charger 20 will now be discussed with reference to FIG. 2.

The battery charger 20 is first activated (step S101). More specifically, when the battery charger 20 is supplied with power supply voltage from an external power supply, the control unit 21 of the battery charger 20 is activated.

Then, the battery charger 20 conducts a self test (step S102). More specifically, the control unit 21 of the battery charger 20 controls the switches SW1 to SW5 to test the connection of each resistor. When a defect is found during the self test (NO in step S103), the self test is repeated (step S102). When a defect is not found during the self test (YES in step S103), the battery charger 20 performs a connection detection process (step S104). Here, the control unit 21 of the battery charger 20 opens the switch SW5 and closes the switch SW1 to measure the voltage at the external terminal TM2. Further, the control unit 21 instructs the reference voltage source 25 to supply the reference voltage V3. When the battery pack 10 is not connected, the external terminal TM2 outputs the reference voltage V0. The comparator CP1 compares the voltage at the external terminal TM2 with the reference voltage V3, which is supplied from the reference voltage source 25, to determine whether or not the battery pack 10 is connected. The connection detection process is continued as long as connection of the battery pack 10 is not detected (NO in step S104).

When connection of the battery pack 10 is detected (YES in step S104), the battery charger 20 performs temperature estimation (step S105). More specifically, the control unit 21 of the battery charger 20 instructs the reference voltage source 25 to supply the reference voltage V2. Then, the control unit 21 sequentially switches the switches SW1 to SW4 and inputs the voltage between the two terminals of the thermistor TH1 to the comparator CP1. The control unit 21 obtains the comparison result of the voltage of the thermistor TH1 and the reference voltage V2 from the comparator CP1 and determines the temperature state of the battery pack 10.

When detecting a temperature abnormality, that is, the measurement result of the temperature being lower than or equal to temperature T1 or higher than or equal to temperature T6 (NO in step S106), the battery charger 20 issues a warning (step S107). More specifically, the control unit 21 of the battery charger 20 generates a warning indication announcing that charging cannot be performed.

When the measurement result of the temperature is in the range of temperature T1 to temperature T6, there is no temperature abnormality (YES in step S106). In such a case, the battery charger 20 determines the charging current (step S108). More specifically, the control unit 21 of the battery charger 20 determines the current value for performing charging in correspondence with the temperature state of the battery pack 10. The control unit 21 also provides the power supply 22 with information related to the determined charging value.

Then, the battery charger 20 starts charging the battery pack 10 (step S109). More specifically, the power supply 22 of the battery charger 20 performs charging with the determined current value. Then, the battery charger 20 measures the charging current value or voltage of the battery cell CL1 in the battery pack 10 to determine charging completion (step S110). When the charging current value or voltage of the battery cell CL1 has not yet satisfied charging completion conditions (NO in step S110), the battery charger 20 continuously repeats processing from the temperature estimation (step S105).

When the charging current value or voltage of the battery cell CL1 satisfies the charging completion conditions (YES in step S110), the battery charger 20 ends the charging (step S111).

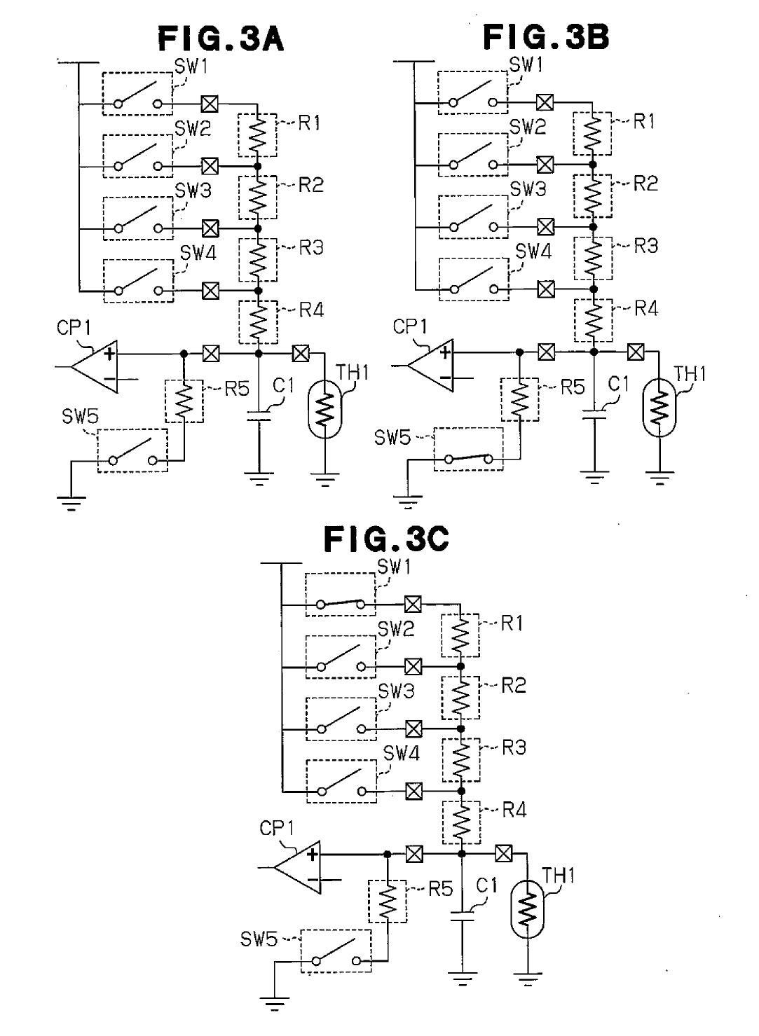

The connection test conducted during the above-described self test (step S102) will now be discussed with reference to FIGS. 3 to 5. The self test includes nine operational states.

In the first operational state, as shown in FIG. 3A, the switches SW1 to SW5 are all open (initial state).

In the second operational state, as shown in FIG. 3B, only the switch SW5 is closed. In this case, the capacitor C1 is discharged via the resistor R5 and the switch SW5. The control unit 21 proceeds to the next operational state when a low signal is obtained from the comparator CP1 and ends the testing when a high signal is obtained from the comparator CP1.

In the third operational state, as shown in FIG. 3C, only the switch SW1 is closed. In this case, the reference voltage V0 is supplied via the switch SW1 to the resistor R1. The reference voltage V0 is distributed to the resistors R1 to R4 and the thermistor TH1 in accordance with each resistance. The voltage distributed to the thermistor TH1 is accumulated in the capacitor C1. This voltage is further supplied to the non-inverting input terminal of the comparator CP1. In this case, the comparator CP1 outputs the result of the comparison between the voltage of the thermistor TH1 and the reference voltage V1. After a period corresponding to a time constant determined by the resistance of the resistors R1 to R4 and the capacitor C1 elapses, the control unit 21 receives the comparison result from the comparator CP1. When the comparison result does not generate a high signal, the control unit 21 returns the switches SW1 to SW5 to the first operational state and ends the testing. When the comparator CP1 outputs a high signal, the control unit 21 proceeds to the next operational state.

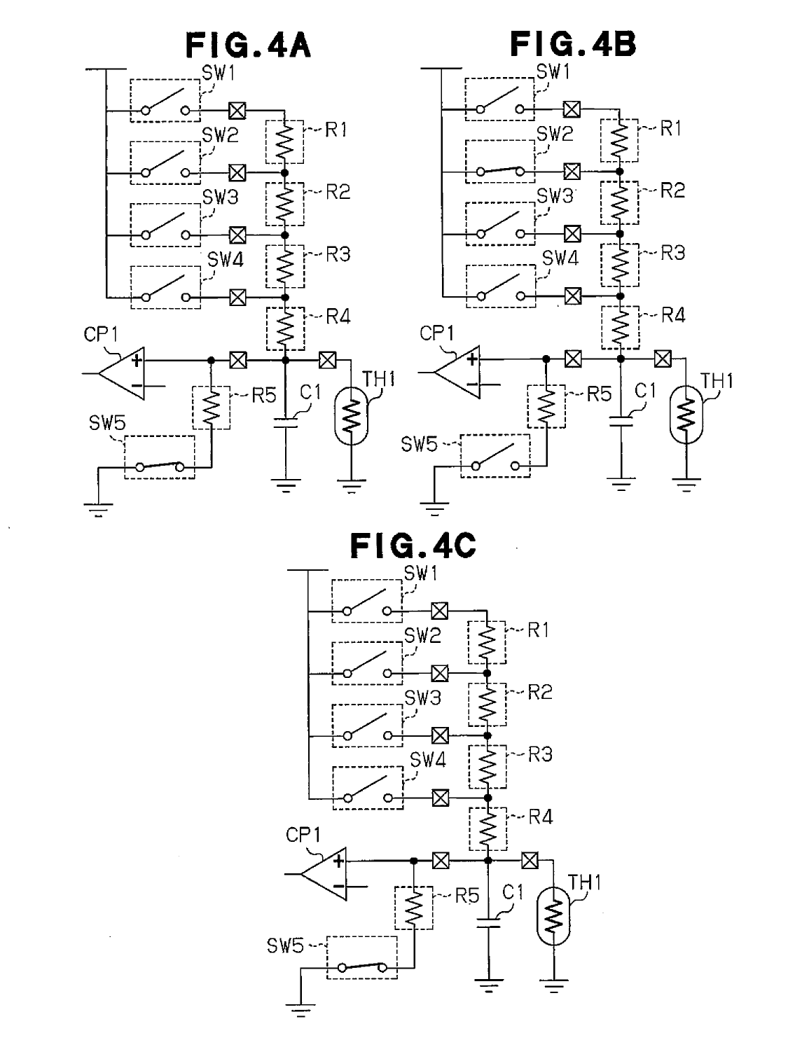

In the fourth operational state, as shown in FIG. 4A, only the switch SW5 is closed. In this case, the capacitor C1 is discharged via the resistor R5 and the switch SW5. The control unit 21 proceeds to the next operational state when a low signal is obtained from the comparator CP1 and ends the testing when a high signal is obtained from the comparator CP1.

In the fifth operational state, as shown in FIG. 4B, only the switch SW2 is closed. In this case, the reference voltage V0 is supplied via the switch SW2 to the resistor R2. The reference voltage V0 is distributed to the resistors R2 to R4 and the thermistor TH1 in accordance with each resistance. The voltage distributed to the thermistor TH1 is accumulated in the capacitor C1. This voltage is further supplied to the non-inverting input terminal of the comparator CP1. In this case, the comparator CP1 outputs the result of the comparison between the voltage of the thermistor TH1 and the reference voltage V1. After a period corresponding to a time constant determined by the resistance of the resistors R2 to R4 and the capacitor C1 elapses, the control unit 21 receives the comparison result from the comparator CP1. When the comparison result does not generate a high signal, the control unit 21 returns the switches SW1 to SW5 to the first operational state and ends the testing. When the comparator CP1 outputs a high signal, the control unit 21 proceeds to the next operational state.

In the sixth operational state, as shown in FIG. 4C, only the switch SW5 is closed. In this case, the capacitor C1 is discharged via the resistor R5 and the switch SW5. The control unit 21 proceeds to the next operational state when a low signal is obtained from the comparator CP1 and ends the testing when a high signal is obtained from the comparator CP1.

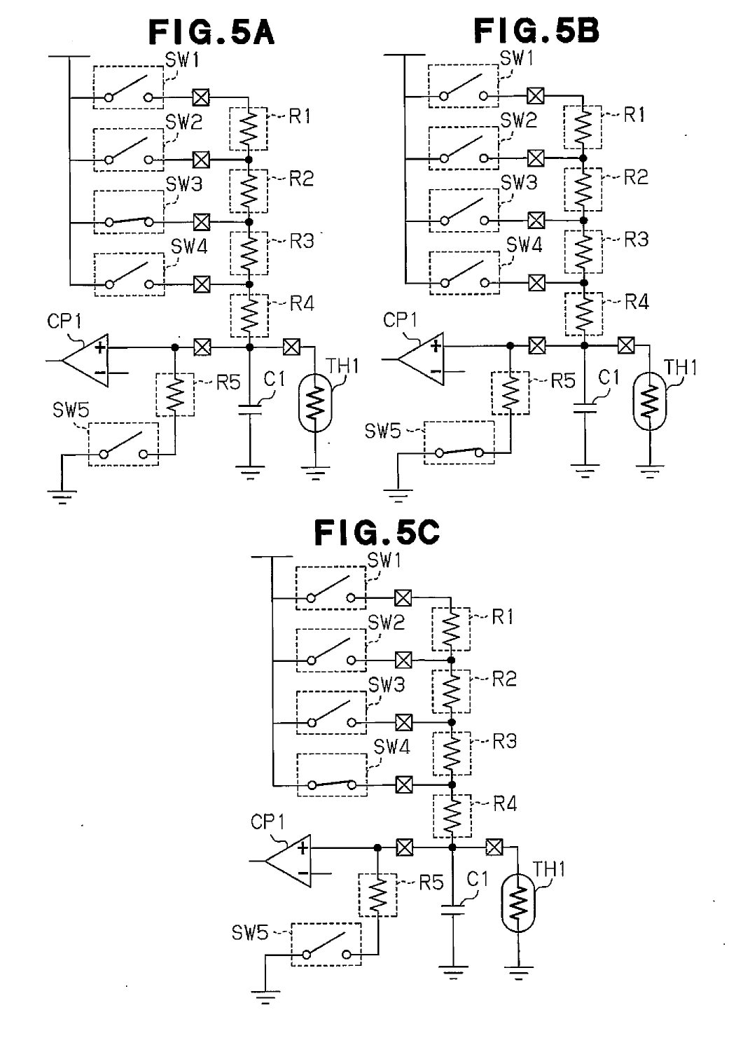

In the seventh operational state, as shown in FIG. 5A, only the switch SW3 is closed. In this case, the reference voltage V0 is supplied via the switch SW3 to the resistor R3. The reference voltage V0 is distributed to the resistors R3 to R4 and the thermistor TH1 in accordance with each resistance. The voltage distributed to the thermistor TH1 is accumulated in the capacitor C1. This voltage is further supplied to the non-inverting input terminal of the comparator CP1. After a period corresponding to a time constant determined by the resistance of the resistors R3 to R4 and the capacitor C1 elapses, the control unit 21 receives the comparison result of the comparator CP1. In this case, the comparator CP1 outputs the result of the comparison between the voltage of the thermistor TH1 and the reference voltage V1. When the comparison result does not generate a high signal, the control unit 21 returns the switches SW1 to SW5 to the first operational state and ends the testing. When the comparator CP1 outputs a high signal, the control unit 21 proceeds to the next operational state.

In the eighth operational state, as shown in FIG. 5B, only the switch SW5 is closed. In this case, the capacitor C1 is discharged via the resistor R5 and the switch SW5. The control unit 21 proceeds to the next operational state when a low signal is obtained from the comparator CP1 and ends the testing when a high signal is obtained from the comparator CP1.

In the ninth operational state, as shown in FIG. 5C, only the switch SW4 is closed. In this case, the reference voltage V0 is supplied via the switch SW4 to the resistor R4. The reference voltage V0 is distributed to the resistor R4 and the thermistor TH1 in accordance with each resistance. The voltage distributed to the thermistor TH1 is accumulated in the capacitor C1. This voltage is further supplied to the non-inverting input terminal of the comparator CP1. After a period corresponding to a time constant determined by the resistance of the resistor R4 and the capacitor C1 elapses, the control unit 21 receives the comparison result of the comparator CP1. In this case, the comparator CP1 outputs the result of the comparison between the voltage of the thermistor TH1 and the reference voltage V1. When the comparison result does not generate a high signal, the control unit 21 returns the switches SW1 to SW5 to the first operational state and ends the testing. When the comparator CP1 outputs a high signal, the control unit 21 increments a count value. When the count value has not yet reached a reference testing count (e.g., two), the control unit 21 repeats the processing from the first operational state.

When the count value reaches the reference testing count, the control unit 21 ends the testing. When the comparison result does not generate a high signal and the switches SW1 to SW5 are returned to the first operational state, charging is stopped and a warning is issued, as described above.

The resistor testing circuit of the first embodiment has the following advantages.

Charging is started after testing the connection state of the divisional resistors. This allows for the connection state of the resistors R1 to R4 to be checked and allows for charging to be performed based on an accurate temperature estimation, which is performed with a thermistor.

The first embodiment may be modified as described below.

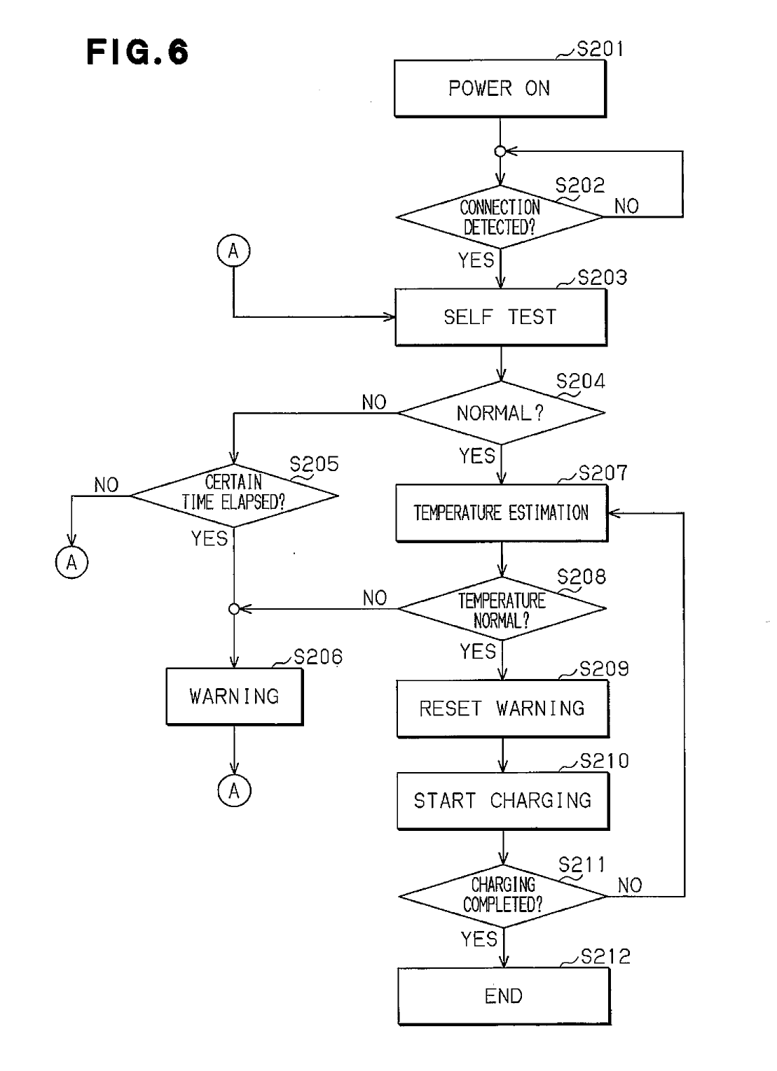

As shown in FIG. 2, the temperature estimation (step S105) is carried out after the self test (step S102) when performing charging. However, the order in which the self test is performed may be varied. One example of such a case will now be described with reference to FIG. 6. Here, the battery charger 20 is first activated (step S201). Then, in the same manner as in step S104, the control unit 21 of the battery charger 20 performs a connection detection process (step S202). The connection detection process is continued as long as connection of the battery pack 10 is not detected (NO in step S202). When connection of the battery pack 10 is detected (YES in step S202), in the same manner as in step S102, the battery charger 20 conducts a self test (step S203). When a defect is detected during the self test (NO in step S204), the battery charger 20 determines whether a predetermined time has elapsed from when the self test was started (step S205). More specifically, the control unit 21 of the battery charger 20 activates a timer when detecting a defect during the self test to measure the elapsed time. Further, the control unit compares the elapsed time with a warning issuance reference time, which is stored beforehand.

When a certain time (warning issuance reference time) has elapsed from the starting of the self test (YES in step S205), the battery charger 20 issues a warning (step S206). More specifically, the control unit 21 of the battery charger 20 generates a warning indication announcing that charging cannot be performed. Then, the control unit 21 of the battery charger 20 continues the self test (step S203).

When a defect has not been detected by the self test (YES in step S204), the battery charger 20 performs temperature estimation (step S207). More specifically, the control unit 21 of the battery charger 20 sequentially switches the switches SW1 to SW4 and inputs the voltage between the two terminals of the thermistor TH1 to the comparator CP1. When detecting a temperature abnormality, that is, the measurement result of the temperature being lower than or equal to temperature T1 or higher than or equal to temperature T6 (NO in step S208), the battery charger 20 issues a warning (step S206).

When the measurement result of the temperature is in the range of temperature T1 to temperature T6 and there is no temperature abnormality (YES in step S208), the battery charger 20 determines the charging current (step S209). Here, when the warning is being output (step S206), the control unit 21 of the battery charger 20 resets the warning. Then, in the same manner as in step S108, the control unit 21 of the battery charger 20 determines the current value for performing charging in correspondence with the temperature state of the battery pack 10. Further, the control unit 21 provides the power supply 22 with information related to the determined charging value.

Next, the battery charger 20 starts charging the battery pack 10 (step S210). Then, the battery charger 20 determines charging completion (step S211). When the charging completion conditions have not yet been satisfied (NO in step S211), the battery charger 20 continuously repeats processing from the temperature estimation (step S207). When the charging completion conditions have been satisfied (YES in step S211), the battery charger 20 ends the charging (step S212).

When the temperature of the battery pack 10 is high, the resistor of the thermistor TH1 is low. This may result in an erroneous detection during the self test. In the above-described example, failure of the self test within a certain time (NO in step S204 and YES in step S205) results in the control unit 21 of the battery charger 20 issuing a warning (step 206). This allows for the issuance of a warning while preventing erroneous detection. Further, the temperature estimation (step S207) is performed when a defect is not found during the self test.

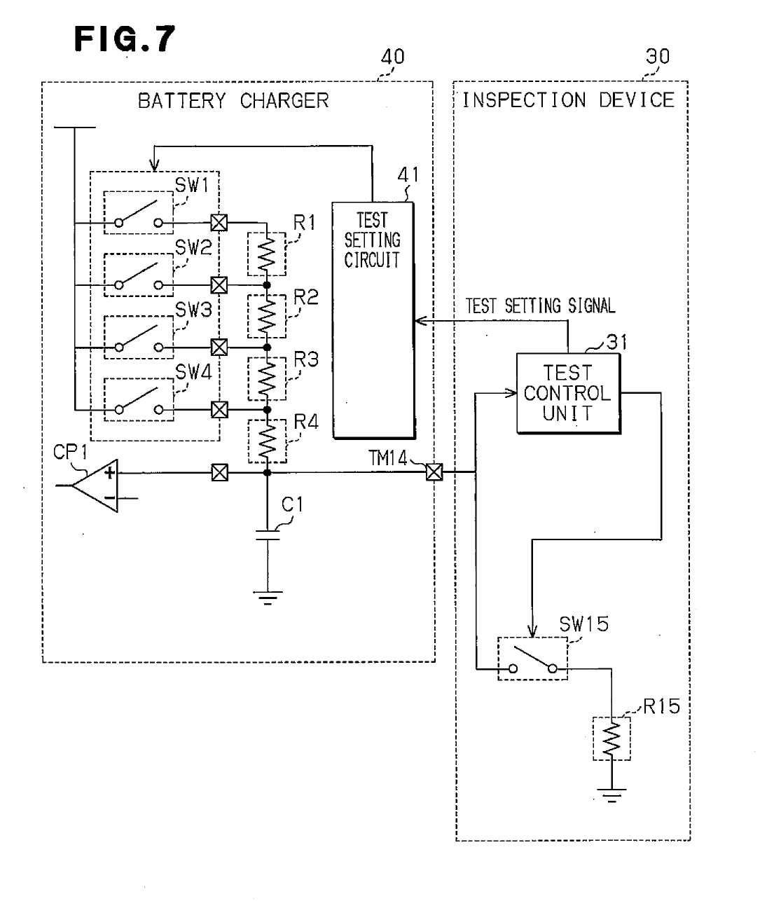

A resistor testing circuit according to a second embodiment of the present invention will now be discussed with reference to FIGS. 7 to 9. In the second embodiment, a battery charger 40 undergoes the testing of the divisional resistors when inspected before being shipped out of the factory.

In the second embodiment, an inspection device 30, which is shown in FIG. 7, is used as the resistor testing circuit. The inspection device 30 includes a test control unit 31, a switch SW15, and a resistor R15. The test control unit 31 controls the switch SW15 and provides the battery charger 40 with a test setting signal.

The battery charger 40 includes switches SW1 to SW4, resistors R1 to R4, a capacitor C1, a comparator CP1, and a test setting circuit 41. The test setting circuit 41 controls the switches SW1 to SW4. The test setting circuit 41 includes a means for controlling internal switches (not shown) and functions, for example, in a test mode. The setting procedures of the test setting circuit 41 are irrelevant with the present invention and will thus not be described here. The test setting circuit 41 controls the switches SW1 to SW4 based on the test setting signal.

The battery charger 40 has a terminal TM14 connected to a connection node of the resistor R4 and the capacitor C1. The terminal TM14 is connected via the switch SW15 to one end of the resistor R15. The other end of the resistor R15, which functions as a dummy resistor, is grounded.

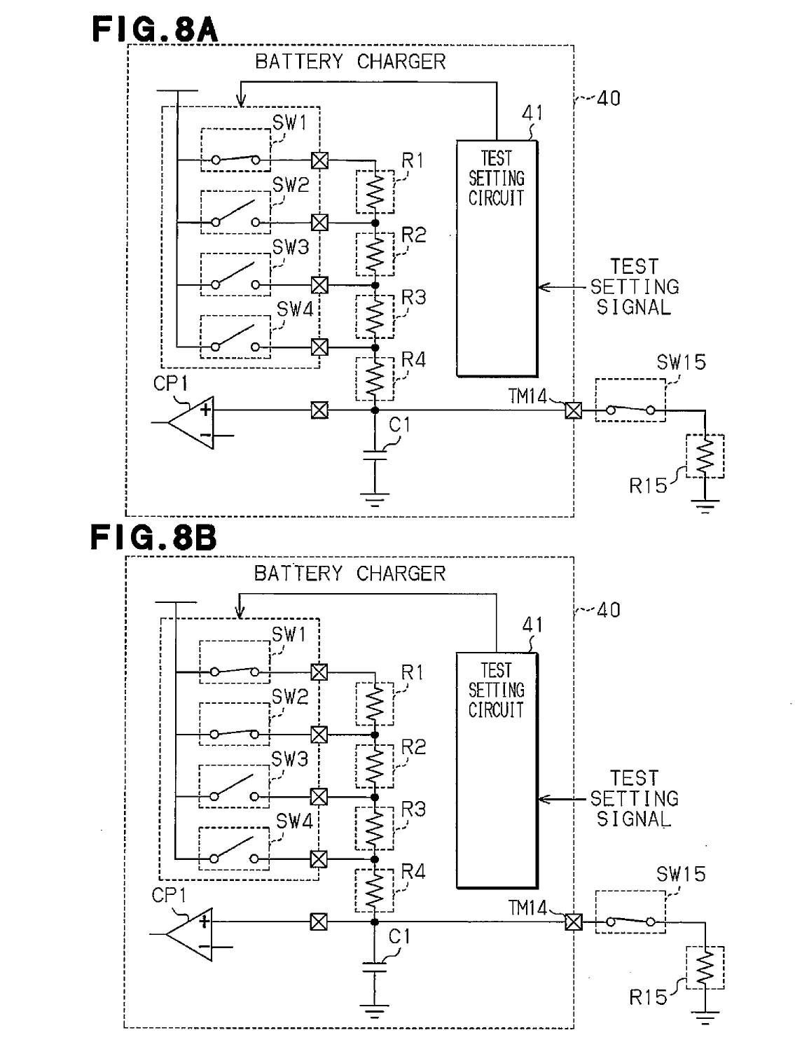

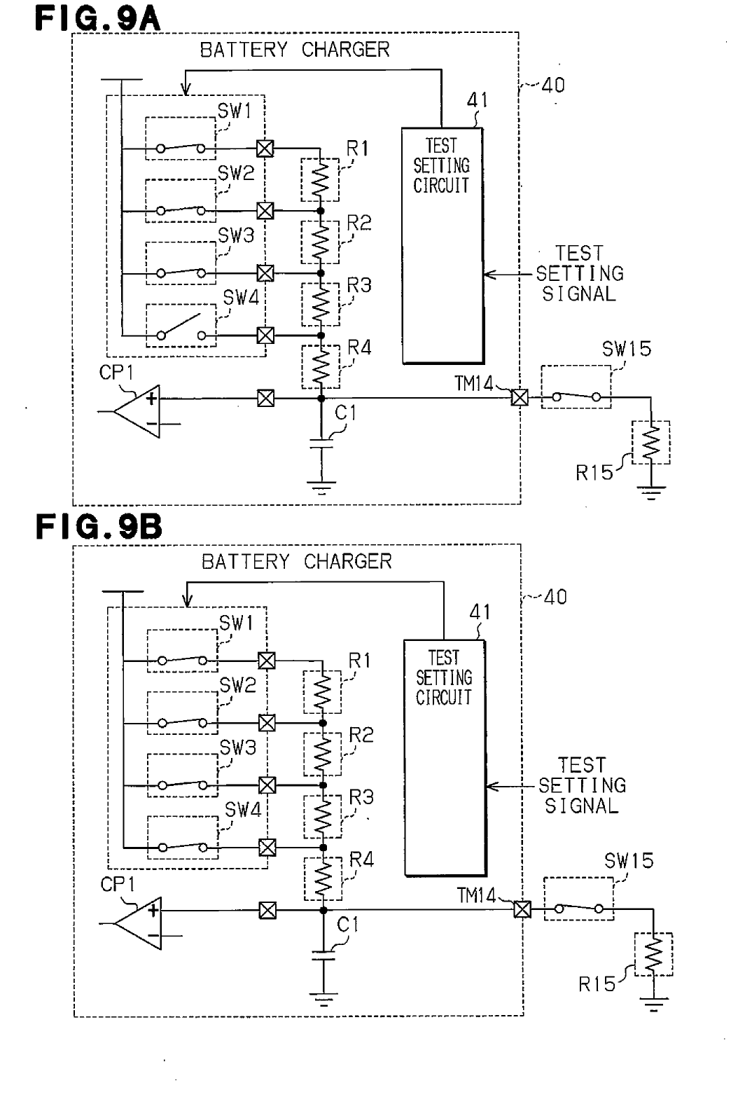

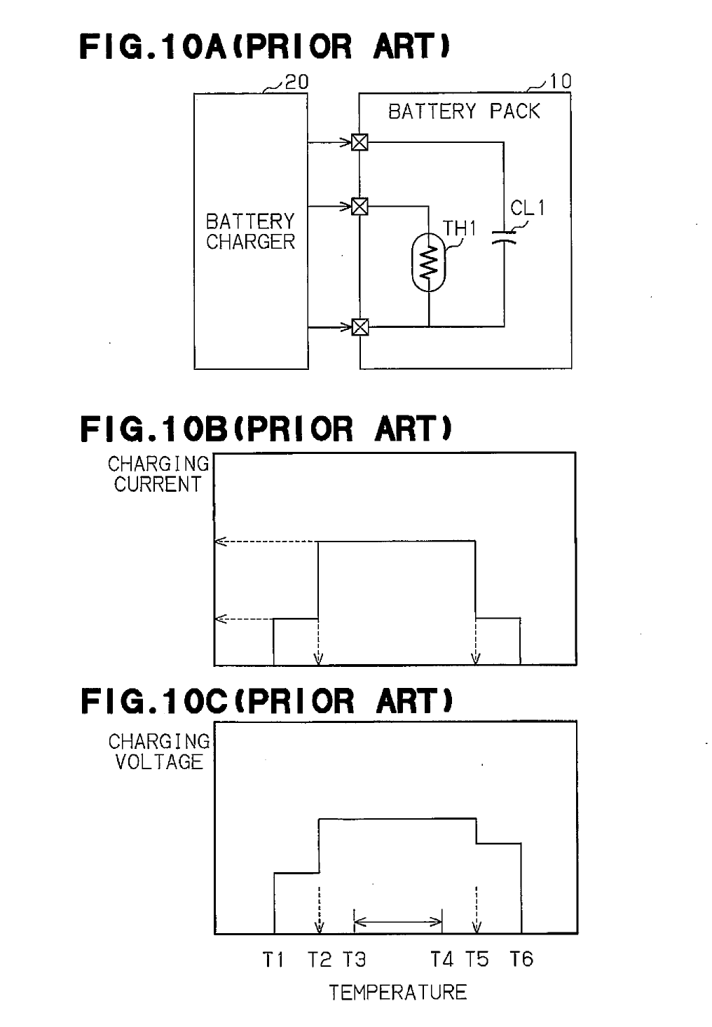

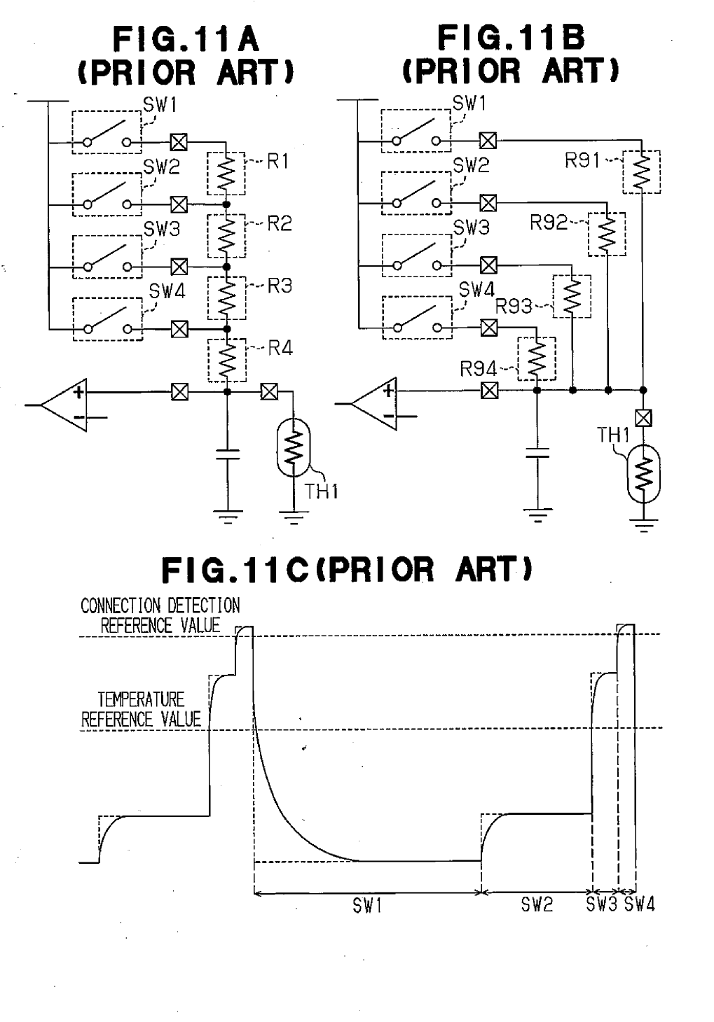

The self test of the second embodiment will now be discussed with reference to FIGS. 8 and 9. In the self test, the test control unit 31 controls four operational states. The self test is conducted before the battery charger 40 is shipped out of the factory in a state in which a battery pack is not connected. The resistor R15 is connected in lieu of a thermistor to the comparator CP1 via the switch SW15.

In the first operational state, as shown in FIG. 8A, the switches SW1 and SW15 are closed. In this state, it is checked whether or not the voltage at the terminal TM14 has a predetermined voltage dividing ratio (voltage dividing ratio of the resistors R1 to R4 and the resistor R15).

In the second operational state, as shown in FIG. 8B, the switches SW1, SW2, and SW15 are closed. In this state, it is checked whether or not the voltage at the terminal TM14 has a predetermined voltage dividing ratio (voltage dividing ratio of the resistors R2 to R4 and the resistor R15).

In the third operational state, as shown in FIG. 9A, the switches SW1, SW2, SW3, and SW15 are closed. In this state, it is checked whether or not the voltage at the terminal TM14 has a predetermined voltage dividing ratio (voltage dividing ratio of the resistors R3 to R4 and the resistor R15).

In the fourth operational state, as shown in FIG. 9B, the switches SW1, SW2, SW3, SW4, and SW15 are closed. In this state, it is checked whether or not the voltage at the terminal TM14 has a predetermined voltage dividing ratio (voltage dividing ratio of the resistor R4 and the resistor R15).

The resistor testing circuit of the second embodiment has the following advantages.

The resistor R15 is connected in lieu of a thermistor. This allows for the connection state of resistors to be tested before the battery charger 40 is shipped out of the factory in a state in which a battery pack is not connected.

It should be apparent to those skilled in the art that the present invention may be embodied in many other specific forms without departing from the spirit or scope of the invention. Particularly, it should be understood that the present invention may be embodied in the following forms.

In the first embodiment, instead of closing only the switch SW4 in the ninth operational state, the switches SW4 and SW5 may be closed. In this case, the voltage dividing ratio of the resistors R4 and R5 and the thermistor TH1 must have more margin than the reference voltage V1. This ensures that the connection of the capacitor C1, the resistor R4, and the thermistor TH1 is checked even when an erroneous detection occurs in a preceding operational state.

The above-described embodiments each use a series type battery charger in which divisional resistors are connected in series. However, the connection form of the divisional resistors is not limited to a series type, and the present invention may be applied to a parallel type battery charger.

In the above-described embodiments, the battery charger sequentially shifts the operational states. However, the order of the operational states is not limited to that of the above-described embodiments. It is only required that the operational states all be sequentially performed in any order to conduct a test.

In the above-described embodiments, the four resistors R1 to R4 are used as the divisional resistors in correspondence with the four temperatures T1 to T4. However, the temperatures that are subjected to evaluation are not limited to four temperatures. When varying the number of subject temperatures, the same number of resistors as the number of subject temperatures are used, and the operational states are set to evaluate each resistor.

The present examples and embodiments are to be considered as illustrative and not restrictive, and the invention is not to be limited to the details given herein, but may be modified within the scope and equivalence of the appended claims.

1. A resistor testing circuit for a battery charger including a plurality of divisional resistors connected in series to a thermistor for measuring the temperature of a battery, a plurality of switches arranged in respective correspondence with each of the divisional resistors to control supply of a reference voltage, a comparator that compares a voltage between the two terminals of the thermistor with the reference voltage, and a power supply that supplies the battery with a charging current, wherein the resistor testing circuit tests a connection state of the divisional resistors, the resistor testing circuit comprising:
the plurality of switches; and
a control unit that controls the power supply, wherein the control unit sequentially switches the switches and obtains a comparison result from the comparator, and conducts a test that allows the power supply to perform charging only when the comparison result is free from abnormalities.

2. The resistor testing circuit of claim 1, wherein the control unit starts the test upon detecting activation of the battery charger.

3. The resistor testing circuit according to claim 1, wherein the battery charger includes a capacitor connected in series to the divisional resistors; and
the control unit switches the switches using time that corresponds to a time constant determined by a resistance of a divisional resistor, which is subjected to the test, and the capacitor.

4. The resistor testing circuit according to claim 1, wherein the control unit detects the temperature of the battery that is connected and determines whether to conduct the test based on the detected temperature.

5. The resistor testing circuit of claim 1, further comprising:
a switch and a dummy resistor connected in series with the divisional resistors, wherein the switch connects the dummy resistor to the divisional resistors so as to conduct the test on the divisional resistors when the battery is not connected to the battery charger.

6. A battery charger, comprising:
a plurality of divisional resistors connected in series to a thermistor for measuring the temperature of a battery;
a plurality of switches arranged in respective correspondence with the divisional resistors to control supply of a reference voltage;
a comparator that compares a voltage between the terminals of the thermistor with the reference voltage;
a power supply that supplies the battery with a charging current; and
a resistor testing circuit including a control unit that controls the switches and the power supply, the resistor testing circuit testing a connection state of the divisional resistors, wherein the control unit sequentially switches the switches and obtains a comparison result from the comparator, and the control unit conducts a test that allows the power supply to perform charging only when the comparison result is free from abnormalities.
